(19) United States
(12) Patent Application Publication
(10) Pub. No.: US 2025/0374596 A1
(43) Pub. Date: Dec. 4, 2025

(54) SEMICONDUCTOR DEVICE AND METHOD FOR FORMING THE SAME

(71) Applicant: Vanguard International Semiconductor Corporation, Hsinchu (TW)

(72) Inventors: Wen-Shan LEE, Hsinchu City (TW); Chung-Yeh LEE, Hsinchu County (TW); Fu-Hsin CHEN, Hsinchu County (TW)

(73) Assignee: Vanguard International Semiconductor Corporation, Hsinchu (TW)

(21) Appl. No.: 18/680,399

(22) Filed: May 31, 2024

(51) Int. Cl. H01L 29/78; H01L 21/308; H01L 29/40; H01L 29/417; H01L 29/423; H01L 29/66

(52) U.S. Cl. CPC H10D 30/668; H01L 21/3086; H10D 12/031; H10D 62/8325; H10D 64/117; H10D 64/256; H10D 64/513

(57) ABSTRACT

A semiconductor device and a method for forming the same are provided. The semiconductor device includes a silicon carbide substrate, an epitaxial layer, a well region, a gate structure, a first insulating pillar, a pair of first dielectric spacers, and a contact feature. The epitaxial layer is disposed on the silicon carbide substrate. The well region is located in the epitaxial layer. The gate structure is disposed in the epitaxial layer. The first insulating pillar is disposed directly above the gate structure and protrudes from the top surface of the epitaxial layer. The first dielectric spacers are disposed on opposite sidewalls of the first insulating pillar. The contact feature extends from above the epitaxial layer into the well region. A first sidewall of the contact feature in the epitaxial layer is aligned with a first outer sidewall of one of the pair of first dielectric spacers.

### BACKGROUND OF THE INVENTION

### Field of the Invention

The present disclosure relates to a semiconductor device and a method for forming the same, and, in particular, to a power transistor device having a self-aligned contact feature and a method for forming the same.

### Description of the Related Art

The semiconductor industry continues to improve the integration density of different electronic components, thereby allowing more components to be integrated in a given area by continuing to reduce the minimum component size. For example, the trench gate metal-oxide-semiconductor field effect transistor (MOSFET), which is widely used in power switches, uses a vertical structure design to increase functional density by reducing cell pitch. The trench gate MOSFET uses the back side of the chip as a drain electrode, and forms the source electrodes and the gate electrodes of multiple transistors on the front side of the chip. Therefore, the driving current flows from the horizontal direction to the vertical direction. The trench gate MOSFET can also enable the semiconductor device to achieve a high reverse withstand voltage and low on-resistance.

However, as the functional density requirements on semiconductor devices continue to increase, the complexity of integrated components in the semiconductor devices and methods for forming semiconductor devices also increases. In addition, some electronic characteristics having performance trade-offs need careful consideration. Although existing semiconductor devices are generally suitable and sufficient for their intended purposes, they have not been entirely satisfactory in all respects.

### BRIEF SUMMARY OF THE INVENTION

An embodiment of the present disclosure provides a semiconductor device. The semiconductor device includes a silicon carbide substrate, an epitaxial layer, a well region, a gate structure, a first insulating pillar, a pair of first dielectric spacers, and a contact feature. The silicon carbide substrate has a first region and a second region. The silicon carbide substrate has a first conductivity type. The epitaxial layer is disposed on a top surface of the silicon carbide substrate. The epitaxial layer has a first conductivity type. The well region is located in the epitaxial layer. The well region has a second conductivity type. The gate structure is disposed in the epitaxial layer of the first region. The gate structure extends in a first direction. The first insulating pillar is disposed directly above the gate structure and protrudes from a top surface of the epitaxial layer in the first direction. The pair of first dielectric spacers is disposed on opposite sidewalls of the first insulating pillar. The contact feature extends from above the epitaxial layer into the well region. A first sidewall of the contact feature in the epitaxial layer is aligned with a first outer sidewall of one of the pair of first dielectric spacers.

Another embodiment of the present disclosure provides a method for forming a semiconductor device. The method for forming a semiconductor device includes providing a silicon carbide substrate. The silicon carbide substrate has a first region and a second region, and the silicon carbide substrate has a first conductivity type. The method further includes growing an epitaxial layer on a top surface of the silicon carbide substrate. The epitaxial layer has the first conductivity type. The method further includes forming a first trench in the epitaxial layer in the first region along a first direction. The method further includes oxidizing a top of the electrode material pillar to form a first insulating pillar. The unoxidized electrode material pillar forms a gate electrode in the first trench. The first insulating pillar protrudes from a top surface of the epitaxial layer in the first direction. The method further includes forming a pair of first dielectric spacers on opposite sidewalls of the first insulating pillar. The method further includes performing an etching process to form a contact hole in the epitaxial layer using the pair of first dielectric spacers as an etching mask. The method further includes forming a contact feature in the contact hole.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure; and

FIGS. 2, 3, 4, 5, 6, 7, 8, 9, 10, 11, 12, 13, 14, 15, 16, 17, 18, 19, and 20 are schematic cross-sectional views of intermediate stages of forming the semiconductor device of FIG. 1 in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In high-density shielded gate trench metal-oxide-semiconductor field-effect transistor (SGT MOSFET) cell arrays, expensive high-resolution masks (such as deep ultraviolet (DUV) masks) and photolithography processes are required to form source contacts between adjacent transistor units. However, during the conventional source contact processes, photoresist rework problem often occurs due to the contact-to-trench overlay error. Therefore, the fabrication cost and manufacturing cycle time are increased. Moreover, the contact-to-trench overlay error will cause the variation of the electrical parameters of adjacent transistor units, thereby causing the failure during device reliability tests (for example, UIS (Unclamped Inductive Switching) electrical tests. The contact-to-trench overlay error may further cause the burnout problem of the components. Therefore, a novel semiconductor device such as a SGT MOSFET and a method for forming the same are desired to solve or improve the abovementioned problems.

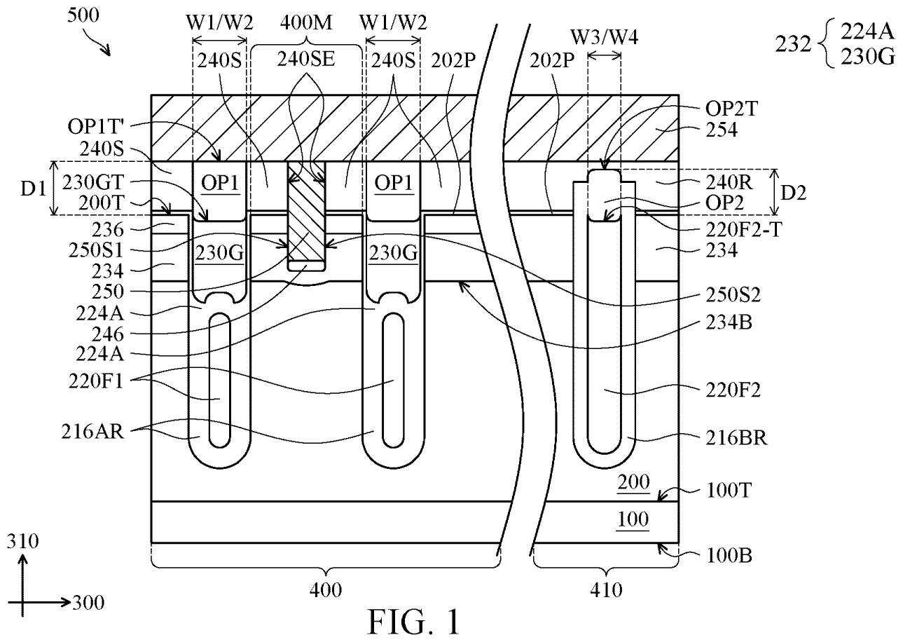

FIG. 1 is a schematic cross-sectional view of a semiconductor device 500 in accordance with some embodiments of the disclosure. In some embodiments, the semiconductor device 500 includes a power metal-oxide-semiconductor field-effect transistor (power MOSFET), such as a shielded gate trench metal-oxide-semiconductor field-effect transistor (SGT MOSFET). As shown in FIG. 1, the semiconductor device 500 includes a silicon carbide (SiC) substrate 100, an epitaxial layer 200, a well region 234, a gate structure 232, an insulating pillar OP1, dielectric spacers 240S, and a contact feature 250.

As shown in FIG. 1, the silicon carbide substrate 100 has a top surface 100T and a bottom surface 100B. Furthermore, the silicon carbide substrate 200 has a first region 400 and a second region 410. In some embodiments, the first region 400 may be a cell region providing a power metal-oxide-semiconductor field-effect transistor array formed within. In addition, the second region 410 may be a termination region, which is used to surround the cell region and serve as a buffer region for a doping region in the cell region to avoid a sudden drop in the device breakdown voltage at the boundary of the cell region. In the following embodiments, two shielded gate trench metal-oxide-semiconductor field-effect transistor units are used as an example for the structural description in the cell region. Furthermore, one trench electrode (for example, a source electrode) is used as an example for the structural description in the terminal region. However, any number of shielded gate trench metal-oxide-semiconductor field-effect transistor units and trench electrodes may be disposed in the cell region and the terminal region, and are not limited to the disclosed embodiments.

In some embodiments, the conductivity type of the silicon carbide substrate 100 may be P-type or N-type according to design requirements of the products. In this embodiment, the silicon carbide substrate 100 may be doped with dopants to have a first conductivity type, such as N-type. In the applications of vertical trench-gate metal-oxide-semiconductor field-effect transistor (vertical trench-gate MOSFET), the silicon carbide substrate 100 having the first conductivity type may be used as the drain region of the resulting semiconductor device 500.

The epitaxial layer 200 is disposed on a top surface 100T of the silicon carbide substrate 100. In some embodiments, the epitaxial layer 200 may be doped with dopants to have the first conductivity type. For example, when the silicon carbide substrate 100 is an N-type silicon carbide substrate 100, the epitaxial layer 200 is an N-type epitaxial layer 200. Moreover, the doping concentration of the epitaxial layer 200 (for example, about 10¹⁵-10¹⁶ atoms/cm³) is lighter than the doping concentration of the silicon carbide substrate 100 (for example, about 10¹⁹-10²¹ atoms/cm³). For example, when the silicon carbide substrate 100 is an N-type heavily doped (N+) silicon carbide substrate 100, the epitaxial layer 200 is an N-type lightly doped (N−) epitaxial layer 200. In the applications of vertical trench-gate metal-oxide-semiconductor field-effect transistor (vertical trench-gate MOSFET), the epitaxial layer 200 having the first conductivity type may serve as a drift region of the resulting semiconductor device 500). In some embodiments, the epitaxial layer 200 includes silicon carbide.

The well region 234 of the semiconductor device 500 is located in the epitaxial layer 200 in the first region 400 and the second region 410 and is close to the top surface 200T of the epitaxial layer 200. In some embodiments, well region 234 may be doped with dopants to have a second conductivity type that is opposite to the first conductivity type. For example, when the silicon carbide substrate 100 is an N-type silicon carbide substrate 100, the well region 234 is a P-type well region 234. Furthermore, the dopant having the second conductivity type may include aluminum (Al), boron (B) or other suitable dopants. In some embodiments, the doping concentration of the well region 234 (e.g., about 10¹⁷-10¹⁸ atoms/cm³) is greater than the doping concentration of the epitaxial layer 200. In some embodiments, an ion implantation process may be used to form the well region 234. In the applications of vertical trench gate metal-oxide-semiconductor field-effect transistors, the well region 234 having the second conductivity type may serve as a channel region of the resulting semiconductor device 500.

The source region 236 of the semiconductor device 500 is located on the well region 234 in the first region 400 and is close to the top surface 200T of the epitaxial layer 200. Furthermore, the source region 236 may not be included in the second region 410. As shown in FIG. 1, the source region 236 is surrounded by the well region 234. In some embodiments, the source region 236 may be doped with dopants to have the first conductivity type. For example, when the silicon carbide substrate 100 is an N-type silicon carbide substrate 100, the source region 236 is an N-type source region 236. Furthermore, the doping concentration of the source region 236 is greater than the doping concentration of the epitaxial layer 200. For example, when the epitaxial layer 200 is an N-type lightly doped (N−) epitaxial layer 200, the source region 236 is an N-type heavily doped (N+) source region 236.

In the embodiment as shown in FIG. 1, at least two gate structures 232 are disposed in the epitaxial layer 200 in the first region 400. The two gate structures 232 are separated from each other by the epitaxial layer 200 along a direction 300 (i.e., the direction that is substantially parallel to the top surface 100T of the silicon carbide substrate 100, and may be also regarded as the lateral direction). Furthermore, the region of the epitaxial layer 200 between the two gate structures 232 may be serve as a mesa region 400M of the semiconductor device 500. As shown in FIG. 1, the gate structure 232 extends in a direction 310 (i.e., the direction that is substantially perpendicular to the top surface 100T of the silicon carbide substrate 100 and substantially perpendicular to the direction 300, and may be also regarded as the longitudinal direction). In some embodiments, the gate structure 232 includes a gate dielectric layer 224A and a gate electrode 230G.

The gate dielectric layer 224A extends from the top surface 200T of the epitaxial layer 200 in the first region 400 into the epitaxial layer 200 along the direction 310. In some embodiments, the gate dielectric layer 224A may be silicon oxide, other suitable dielectric materials, or a combination thereof. In some embodiments, the gate dielectric layer 224A may be formed by an oxidation process. In some embodiments, the oxidation process may include thermal oxidation or another suitable process.

The gate electrode 230G is located on the gate dielectric layer 224A. As shown in FIG. 1, a top surface 230GT of the gate electrode 230G may be lower than the top surface 200T of the epitaxial layer 200. Furthermore, the gate dielectric layer 224A covers a bottom surface and opposite sidewalls of the gate electrode 230G. In some embodiments, the gate electrode 230G may be a single-layer structure or multi-layer structure and formed of amorphous silicon, polycrystalline silicon, one or more kinds of metals, metal nitride, metal silicide, conductive metal oxide, or a combination thereof. In some embodiments, the metal may include, but are not limited to, tungsten (W), titanium (Ti), tantalum (Ta) or platinum (Pt). In some embodiments, the metal nitrides may include, but are not limited to, titanium nitride (TiN) or tantalum nitride (TaN). In some embodiments, the metal silicide may include, but is not limited to, tungsten silicide (WSiₓ). In some embodiments, the gate electrode 230G may optionally include a dopant of the second conductivity type. For example, when the silicon carbide substrate 100 is an N-type silicon carbide substrate 100, the gate electrode 230G is a P-type gate electrode 230G. Furthermore, the dopant having the second conductivity type may include aluminum (Al), boron (B), boron difluoride (BF₂) or other suitable dopants.

The semiconductor device 500 further includes a shielding dielectric layer 216AR and a first electrode 220F1. As shown in FIG. 1, the shielding dielectric layer 216AR and the first electrode 220F1 are disposed in the epitaxial layer 200 of the first region 400. The first electrode 220F1 is located directly below the gate structure 232 and extends toward the silicon carbide substrate 100 along the direction 310. The first electrode 220F1 is located on the shielding dielectric layer 216AR. In addition, the shielding dielectric layer 216AR covers a bottom surface and opposite sidewalls of the first electrode 220F1. Furthermore, a top surface of the first electrode 220F1 close to the gate electrode 230G is separated from the gate electrode 230G by the gate dielectric layer 224A.

In some embodiments, the first electrode 220F1 may reduce the gate-to-drain capacitance (Cgd) to improve the switching characteristics of the semiconductor device 500. In addition, the first electrode 220F1 c, such that the distribution of the electric field distribution of the gate dielectric layer 224A close to the bottom of the gate electrode 230G is relatively uniform and the breakdown voltage is increased. Therefore, the reliability of the gate dielectric layer 224A is improved.

The semiconductor device 500 further includes a shielding dielectric layer 216BR and a second electrode 220F2. As shown in FIG. 1, the shielding dielectric layer 216BR and the second electrode 220F2 are disposed in the epitaxial layer 200 in the second region 410. The second electrode 220F2 extends from a position close to the top surface 200T of the epitaxial layer 200 toward to the silicon carbide substrate 100 along the direction 310. The second electrode 220F2 is located on the shielding dielectric layer 216BR. In addition, the shielding dielectric layer 216BR covers a bottom surface and opposite sidewalls of the second electrode 220F2.

In some embodiments, the shielding dielectric layers 216AR and 216BR may include the same material. For example, the shielding dielectric layers 216AR and 216BR may include silicon oxide, other suitable semiconductor oxide materials, or a combination thereof. In some embodiments, the shielding dielectric layers 216AR, 216BR and the gate dielectric layer 224A may be made of the same or different materials according to actual requirements of products. In some embodiments, the shielding dielectric layers 216AR and 216BR may be formed using a conformably deposition process, an oxidation process, or another suitable process. In some embodiments, the oxidation process may be thermal oxidation or another suitable process. In some embodiments, the deposition process may be a physical vapor deposition (PVD) process, a chemical vapor deposition (CVD) process, a plasma-enhanced chemical vapor deposition (PECVD) process, another suitable process, or a combination thereof.

In some embodiments, the first electrode 220F1 and the second electrode 220F2 may include the same or different materials as the gate electrode 230G. In some embodiments, the first electrode 220F1 and the second electrode 220F2 may selectively include a dopant of the second conductivity type. For example, when the silicon carbide substrate 100 is an N-type silicon carbide substrate 100, the first electrode 220F1 and the second electrode 220F2 are respectively a P-type first electrode 220F1 and a P-type second electrode 220F2. Furthermore, the dopant having the second conductivity type may include aluminum (Al), boron (B), boron difluoride (BF₂) or other suitable dopants.

The insulating pillar OP1 is located in the first region 400. The insulating pillar OP1 is disposed directly above the gate structure 232 and protrudes from the top surface 200T of the epitaxial layer 200 along the direction 310. As shown in FIG. 1, the insulating pillar OP1 completely covers and is in contact with the top surface 230GT of the gate electrode 230G. In the direction 300, a width W1 of the gate electrode 230G may be the same as a width W2 of the insulating pillar OP1. In some embodiments, the insulating pillar OP1 may include silicon oxide, other suitable semiconductor oxide materials, or a combination thereof. In some embodiments, the insulating pillar OP1 may be formed using an oxidation process or another suitable process. In some embodiments, the oxidation process may be thermal oxidation or another suitable process.

The semiconductor device 500 may further include an insulating pillar OP2. The insulating pillar OP2 is located in the second region 410 and is disposed directly above the second electrode 220F2 and protrudes from the top surface 200T of the epitaxial layer 200 along the direction 310. As shown in FIG. 1, the insulating pillar OP2 completely covers and contacts a top surface 220F2-T of the second electrode 220F2. In the direction 300, a width W3 of the second electrode 220F2 is the same as a width W4 of the insulating pillar OP2. In some embodiments, the width W4 is less than the width W2. In the direction 310, a distance D1 between a top surface OP1T′ of the insulating pillar OP1 and the top surface 200T of the epitaxial layer 200 is greater than a distance D2 between a top surface OP2T of the insulating pillar OP2 and the top surface 200T of the epitaxial layer 200. In some embodiments, the insulating pillars OP1 and OP2 may include the same or similar materials or processes.

The semiconductor device 500 includes one or more pairs of dielectric spacers 240S disposed on the opposite sidewalls of the corresponding insulating pillars OP1. In one embodiment shown in FIG. 1, the semiconductor device 500 includes two pairs of dielectric spacers 240S. In some embodiments, the dielectric spacer 240S may include silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glass (OSG), low dielectric constant dielectric materials, and/or other suitable dielectric materials, or a combination thereof. In some embodiments, the dielectric spacers 240S may be formed using a conformably deposition process, other suitable formation processes, and a subsequent etch-back process. In some embodiments, the deposition process may include spin-on coating, chemical vapor deposition (CVD), atomic layer deposition (ALD), low pressure chemical vapor deposition (LPCVD), high density plasma chemical vapor deposition (HDPCVD), another suitable process, or a combination thereof.

As shown in FIG. 1, the contact feature 250 is disposed between the two adjacent gate structures 232 along the direction 300. Furthermore, the contact feature 250 is disposed between the two adjacent pairs of dielectric spacers 240S along the direction 300. As shown in FIG. 1, the contact feature 250 is adjacent to the two dielectric spacers 240S of the two pairs of dielectric spacers 240S that are close to each other. Specifically, as shown in FIG. 1, the contact feature 250 is adjacent to one of the left pair of dielectric spacers 240S and adjacent to one of the right pair of dielectric spacers 240S. The contact feature 250 may extend into a portion of epitaxial layer 200 along direction 310. Furthermore, the contact feature 250 may extend from above the epitaxial layer 200 to the well region 234 of the first region 400 along the direction 310. In addition, the contact feature 250 may be located above a bottom surface 234B of the well region 234. In some embodiments, sidewalls 250S1 and 250S2 of the contact feature 250 on the top surface 200T of the epitaxial layer 200 are respectively in contact with outer sidewalls 240SE of the two dielectric spacers 240S of the two pairs of dielectric spacers 240S that are close to each other. In other words, there are no other features located between the sidewalls 250S1 and 250S2 of the contact feature 250 and the two adjacent dielectric spacers 240S. Furthermore, the sidewalls 250S1 and 250S2 of the contact feature 250 in the epitaxial layer 200 are respectively aligned with the outer sidewalls 240SE of the two pairs of dielectric spacers 240S that are close to each other. The outer sidewalls 240SE of the dielectric spacers 240S are away from the corresponding insulating pillars OP1.

In some embodiments, the contact feature 250 may include a contact barrier layer (not shown) and a contact conductive layer (not shown). In some embodiments, the contact barrier layer may be used to prevent subsequently formed contact conductive layer from diffusing into the dielectric spacer 240S (formed from an interlayer dielectric layer). The contact barrier layer may be formed of a material including titanium (Ti), titanium nitride (TiN), tantalum (Ta), tantalum nitride (TaN), cobalt (Co), other suitable barrier materials, or a combination thereof. In some embodiments, the contact barrier layer may be formed using a chemical vapor deposition (CVD) process, an atomic layer deposition (ALD) process, a physical vapor deposition (PVD) process, another suitable process, or a combination thereof.

In some embodiments, the contact conductive layer of the contact feature 250 may be a single-layer structure or a multi-layer structure. The contact conductive layer may be formed of a material including tungsten (W), aluminum (Al), copper (Cu), titanium (Ti), tantalum (Ta), titanium nitride (TiN), tantalum nitride (TaN), nickel silicide (NiSi), cobalt silicide (CoSi), other suitable metals, or a combination thereof. In some embodiments, the contact conductive layer may be formed using a chemical vapor deposition (CVD) process, an atomic layer deposition (ALD) process, a physical vapor deposition (PVD) process, another suitable process, or a combination thereof.

As shown in FIG. 1, the semiconductor device 500 may further include a metal layer 254. The metal layer 254 may cover the contact feature 250 and may be in physical and electrical contact with the contact feature 250. The metal layer 254 may be used as the topmost metal layer of the resulting semiconductor device 500. In addition, the metal layer 254 may be electrically connected to the source region 236 and the well region 234 through the contact feature 250. Therefore, the metal layer 254 may be also called a source metal layer 254. In addition, the metal layer 254 may be electrically connected to the first electrode 220F1 and the second electrode 220F2 through other interconnections (not shown).

In some embodiments, the metal layer 254 may include copper, silver, gold, aluminum, tungsten, other suitable metal materials, or a combination thereof. In some embodiments, the metal layer 254 and the contact feature 250 may include the same material, or different materials.

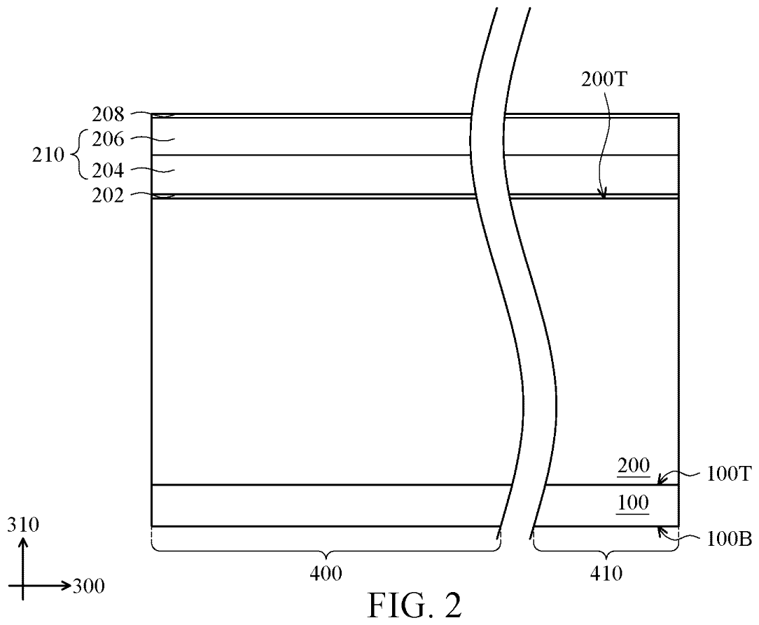

The method for forming the semiconductor device 500 in accordance with some embodiments of the disclosure will be described with reference to FIGS. 2 to 20. FIGS. 2 to 20 are schematic cross-sectional views of intermediate stages of forming the semiconductor device 500 of FIG. 1 in accordance with some embodiments of the disclosure, in which the reference numbers the same or similar to those in FIG. 1 denote the same or similar elements.

As shown in FIG. 2, a silicon carbide substrate 100 having the first conductivity type, for example, an N-type heavily doped (N+) silicon carbide substrate 100, is provided.

Next, an epitaxial growth process is performed to grow an epitaxial layer 200 of the first conductivity type, such as an N-type lightly doped (N−) silicon carbide epitaxial layer 200, on the top surface 100T of the silicon carbide substrate 100. In some embodiments, the epitaxial process includes metal organic chemical vapor deposition (MOCVD), plasma-enhanced chemical vapor deposition (PECVD), molecular beam epitaxy (MBE), hydride vapor phase epitaxy (HVPE), liquid phase epitaxy (LPE), chloride vapor phase epitaxy (Cl-VPE), other suitable epitaxial growth processes or a combination thereof.

Next, a pad oxide layer 202 is formed on the top surface 200T of the epitaxial layer 200 by surface oxidation of the epitaxial layer 200. Then, several deposition processes are performed to form a mask layer 210 on the pad oxide layer 202. In some embodiments, the mask layer 210 is a multi-layer structure. For example, the mask layer 210 includes a first mask layer 204 and a second mask layer 206 located on the first mask layer 204. In some embodiments, the first mask layer 204 and the second mask layer 206 include different insulating materials. For example, the first mask layer 204 may include silicon nitride. The second mask layer 206 may include silicon oxide. The arrangement of the pad oxide layer 202 may avoid excessive stress caused by direct contact between the first mask layer 204 of silicon nitride and the epitaxial layer 200 (for example, including silicon carbide). Next, a deposition process is performed to form an anti-reflective layer 208 on the mask layer 210.

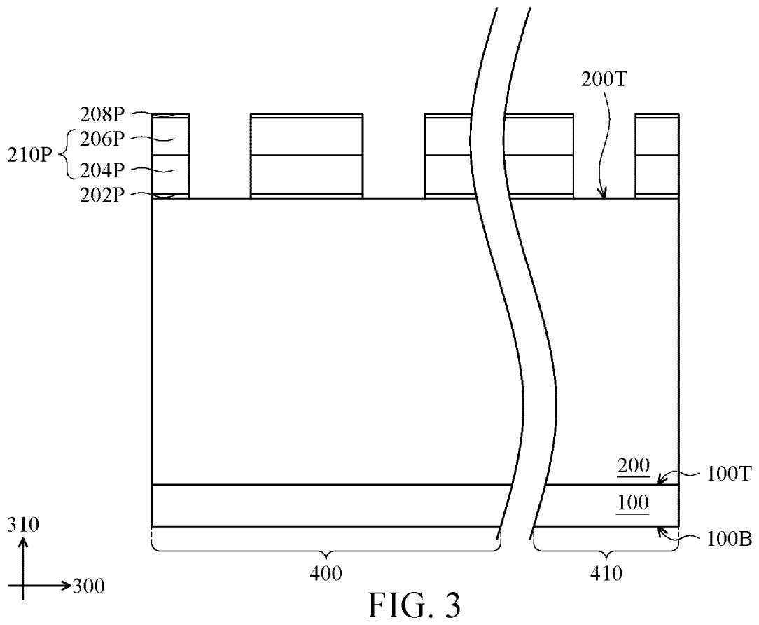

Next, as shown in FIG. 3, a photolithography process and a subsequent patterning process are performed to remove a portion of the anti-reflective layer 208, the mask layer 210 and the underlying pad oxide layer 202, thereby forming a patterned anti-reflective layer 208P, a mask pattern 210P and an underlying pad oxide layer 202P on the top surface 200T of the epitaxial layer 200 and exposing a portion of the top surface 200T of the epitaxial layer 200 to define the formation location of trenches. The mask pattern 210P may include a first mask pattern 204P and a second mask pattern 206P located on the first mask pattern 204P.

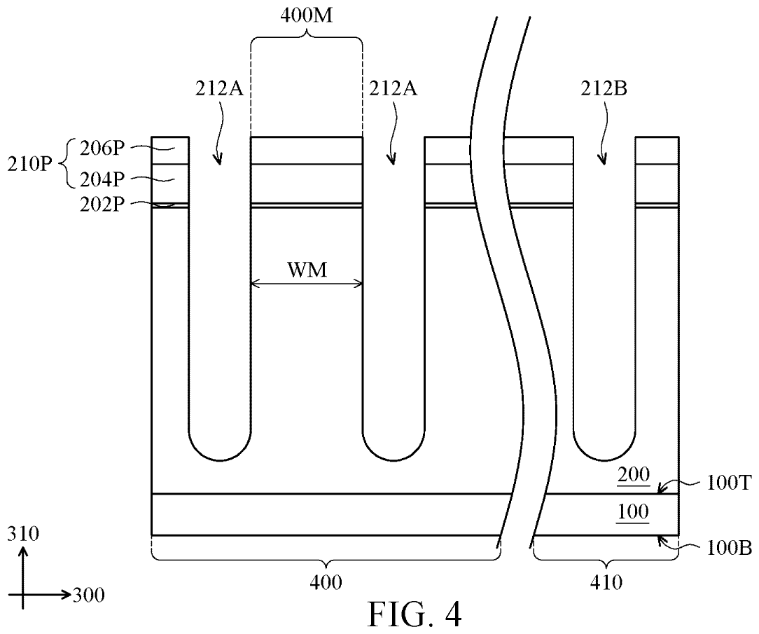

Next, as shown in FIG. 4, an etching process is performed on the epitaxial layer 200 using the mask pattern 210P as an etching mask. The etching process removes the epitaxial layer 200 not covered by the mask pattern 210P to form trenches 212A and 212B in the epitaxial layer 200 in the first region 400 and the second region 410 respectively along the direction 310. In one embodiment shown in FIG. 4, the etching process may form two trenches 212A in the epitaxial layer 200 in the first region 400, and form one trench 212B in the epitaxial layer 200 in the second region 410. The two adjacent trenches 212A are spaced apart from each other along the direction 300 and define the mesa region 400M of the epitaxial layer 200. In some embodiments, the mesa region 400M has a mesa width WM along the direction 300. In some embodiments, the etching process includes dry etching. Dry etching may include plasma etching, plasma-free gas etching, sputter etching, ion milling, reactive ion etching (RIE), neutral beam etch (NBE), inductive coupled plasma etch (inductive coupled plasma etch) or another suitable process. Furthermore, the anti-reflective layer 208 may be removed during the etching process.

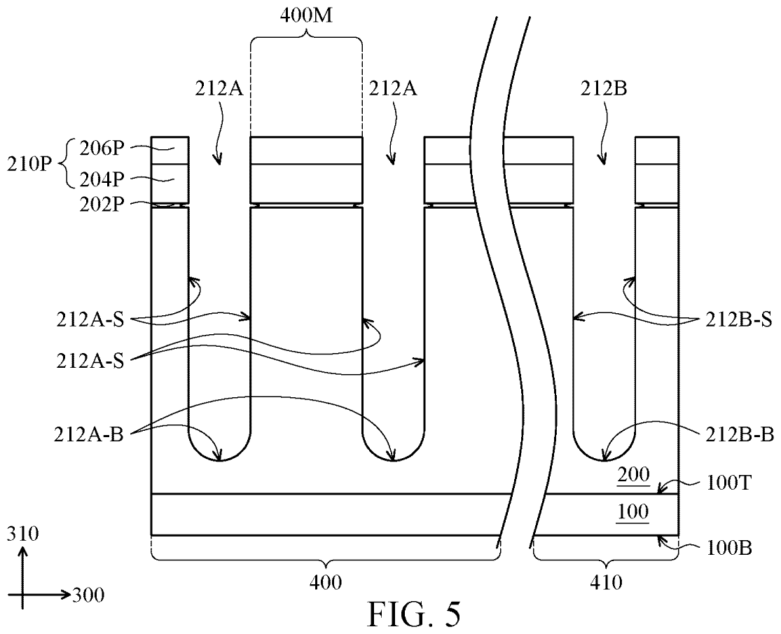

Next, as shown in FIG. 5, an oxidation process and a subsequent etching process may be performed to form a sacrificial (SAC) oxide layer (not shown) on sidewalls 212A-S and 212B-S and bottom surfaces 212A-B and 212B-B of the trenches 212A and 212B. Another etching process is then performed to remove the sacrificial oxide layer, so that the sidewalls 212A-S and 212B-S and the bottom surfaces 212A-B and 212B-B of the trenches 212A and 212B are exposed again. The oxidation process and etching process shown in FIG. 5 may remove the surface damage caused by the etching process (FIG. 4) that forms trenches 212A and 212B. The oxidation process and etching process shown in FIG. 5 may also remove a portion of the pad oxide layer 202P form the sidewalls 212A-S, 212B-S of the trenches 212A and 212B.

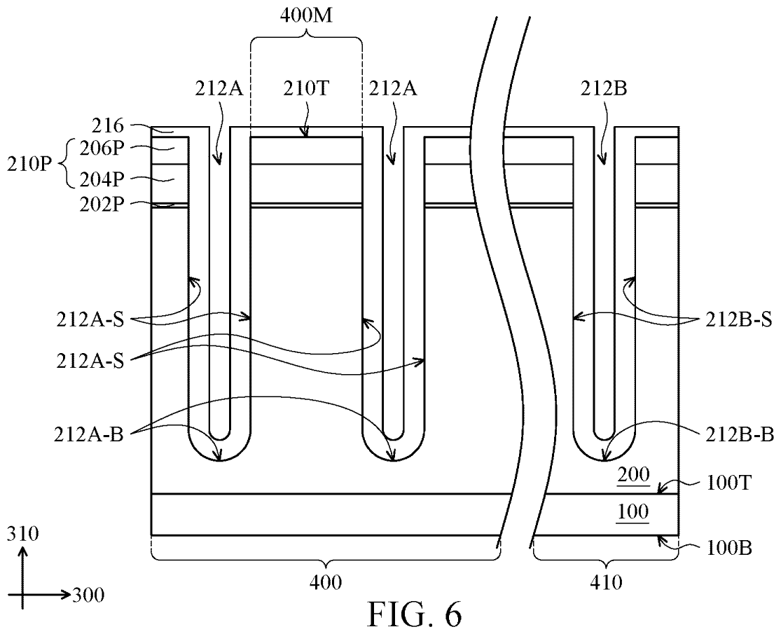

Next, as shown in FIG. 6, an oxidation process and a subsequent deposition process may be performed to entirely form a shielding dielectric layer 216. The shielding dielectric layer 216 may cover the top surface 210T of the mask pattern 210P and extend into the trenches 212A, 212B. In addition, the shielding dielectric layer 216 may conformally cover the sidewalls 212A-S, 212B-S and the bottom surface 212A-B, 212B-B of the trenches 212A, 212B.

The dielectric layer 216 may be optionally subjected to a thermal process to increase the density of the shielding dielectric layer 216 and improve the interface properties between the shielding dielectric layer 216 and the epitaxial layer 200. In some embodiments, the thermal process may be a rapid thermal annealing (RTA) process.

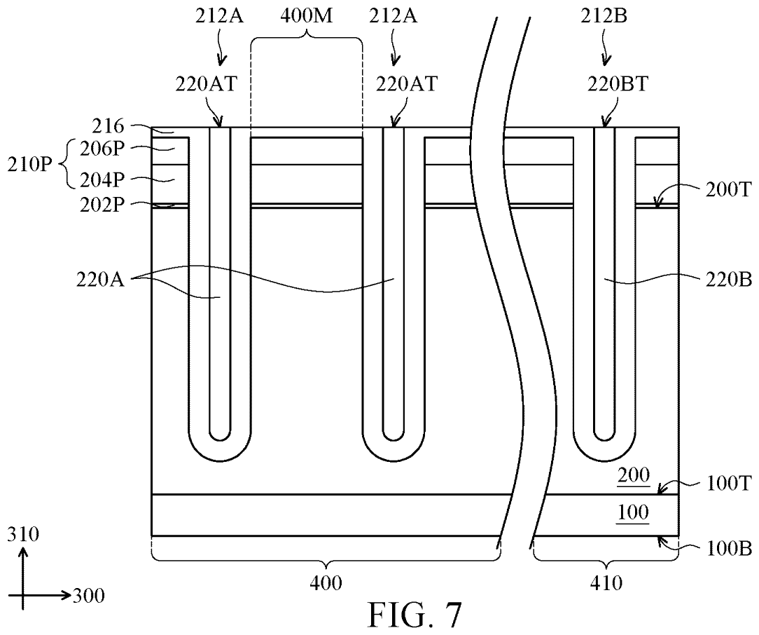

Next, as shown in FIG. 7, a deposition process and a subsequent planarization process may be performed to form conductive materials 220A and 220B in the trenches 212A and 212B respectively. In some embodiments, the conductive materials 220A and 220B are formed simultaneously. A top surface 220AT of the conductive material 220A and a top surface 220BT of the conductive material 220B are both higher than the top surface 200T of the epitaxial layer 200 and aligned each other. In addition, the conductive materials 220A and 220B include the same material. In some embodiments, the conductive materials 220A and 220B may be formed of amorphous silicon, polycrystalline silicon, one or more kinds of metals, metal nitrides, metal silicides, conductive metal oxides, or a combination thereof. In some embodiments, the metals may include, but are not limited to, tungsten (W), titanium (Ti), tantalum (Ta), and platinum (Pt). In some embodiments, the metal nitrides may include, but are not limited to, titanium nitride (TiN) and tantalum nitride (TaN). In some embodiments, the metal silicides may include, but is not limited to, tungsten silicide (WSiₓ). In some embodiments, the deposition process may include metal organic chemical vapor deposition (MOCVD), sputtering, resistance heating evaporation, electron beam evaporation, or other suitable deposition processes. In some embodiments, the planarization process includes a chemical mechanical polishing (CMP) process.

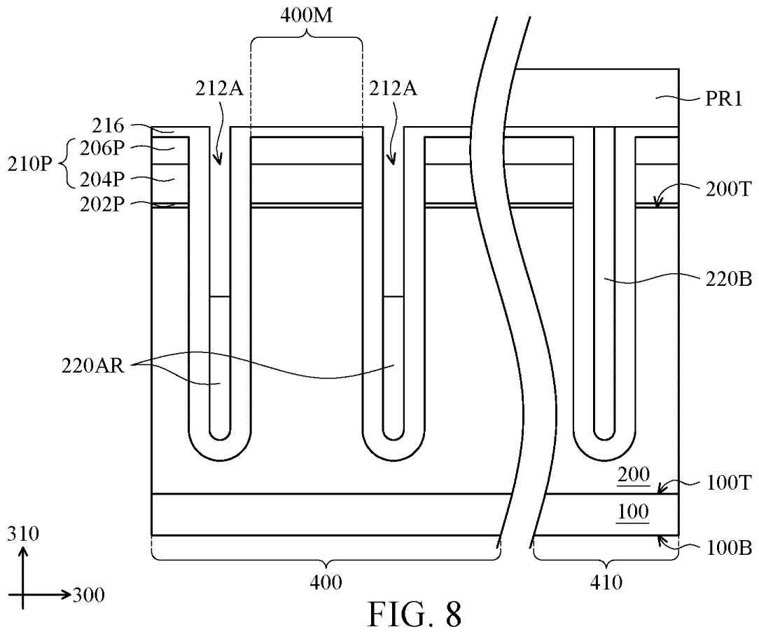

Next, as shown in FIG. 8, a photolithography process may be performed to form a photoresist pattern PR1 over the epitaxial layer 200 in the second region 410. The photoresist pattern PR1 may cover the conductive material 220B and a portion of the shielding dielectric layer 216 in the second region 410. In addition, the top surface 220AT (FIG. 7) of the conductive material 220A in the first region 400 may be exposed from the photoresist pattern PR1. Next, a selective etching process may be performed to remove a portion of the conductive material 220A from the upper portion of the trench 212A close to the top surface 200T of the epitaxial layer 200 (FIG. 7). After performing the selective etching process, the remaining conductive material 220A is denoted as a conductive material 220AR. The conductive material 220AR may fill the lower portion of the trench 212A away from the top surface 200T of the epitaxial layer 200. In addition, the shielding dielectric layer 216 in the upper portion of the trench 212A is exposed. In some embodiments, the selective etching process includes dry etching.

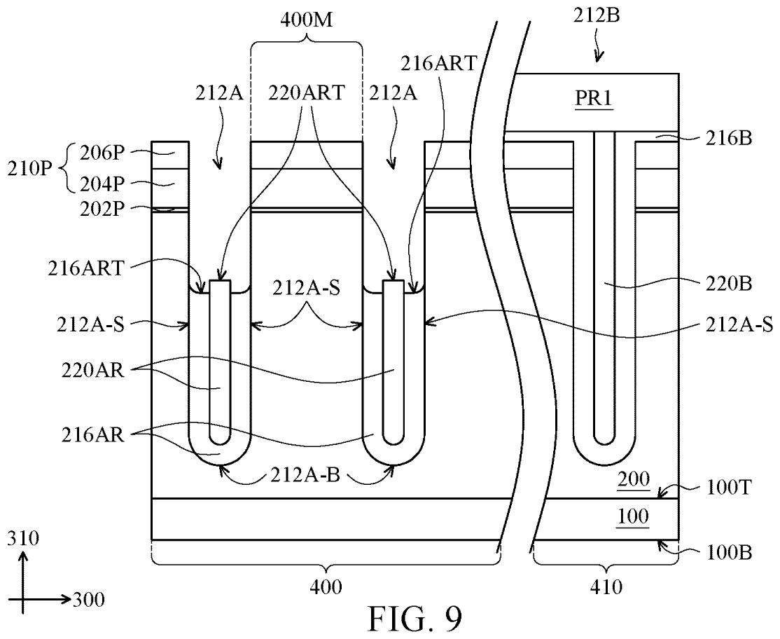

Next, as shown in FIG. 9, another etching process may be performed to remove a portion of the shielding dielectric layer 216 that is not covered by the remaining conductive material 220AR (FIG. 8). After the etching process is performed, the shielding dielectric layer 216 remaining in the trench 212A in the first region 400 is denoted as the shielding dielectric layer 216AR, and the shielding dielectric layer 216 covered by the photoresist pattern PR1 in the second region 410 is denoted as a shielding dielectric layer 216B. The shielding dielectric layer 216AR is located on the sidewalls 212A-S of the lower portion and the bottom surface 212A-B of the trench 212A. In some embodiments, a top surface of the shielding dielectric layer 216AR may be higher than (not shown), lower than, or substantially co-planar with the top surface of the conductive material 220AR. In one embodiment shown in FIG. 9, a top surface 216ART of the shielding dielectric layer 216AR may be lower than a top 220ART of the conductive material 220AR and may have a slightly dishing. In some embodiments, the etching process includes wet etching. After forming the shielding dielectric layers 216AR and 216B, the photoresist pattern PR1 is removed.

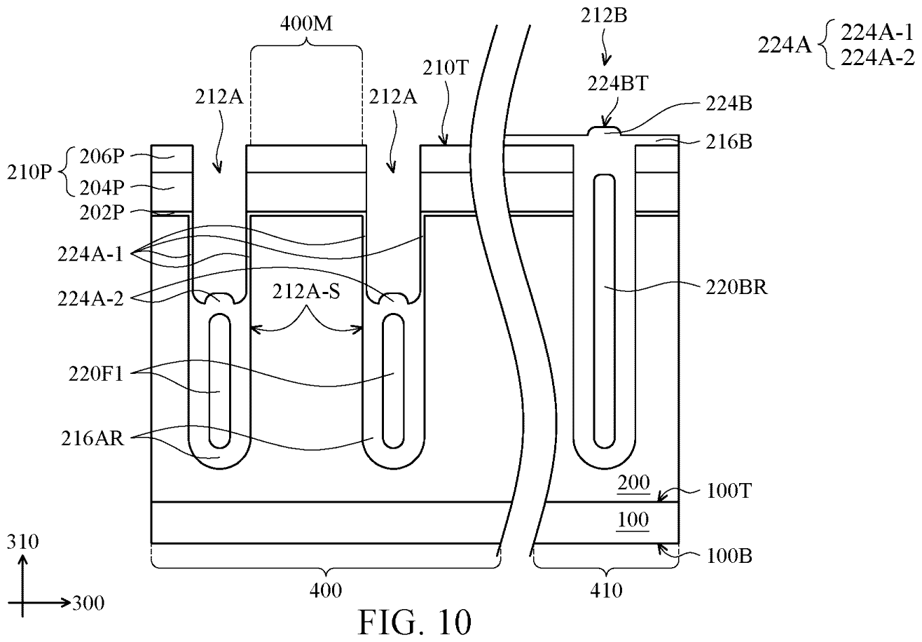

Next, as shown in FIG. 10, an oxidation process may be performed to form a gate dielectric layer 224A in the trench 212A and an oxide layer 224B in the trench 212B. The oxidation process may be performed including oxidizing the upper sidewalls 212A-S of the trench 212A and the top 220ART of the conductive material 220AR (FIG. 9) to form a gate dielectric layer 224A and a first electrode 220F1 in the trench 212A. The oxidation process may be performed further including oxidizing the top of the conductive material 220B in the second region 410 to form an oxide layer 224B and a conductive material 220BR in the trench 212B. In some embodiments, the gate dielectric layer 224A does not fill up the trench 212A. Furthermore, the gate dielectric layer 224A includes a gate dielectric layer 224A-1 conformably formed on the sidewalls 212A-S above the trench 212A, and a gate dielectric layer 224A-2 formed on the first electrode 220F1. In some embodiments, the thickness of gate dielectric layer 224A-1 is less than the thickness of shielding dielectric layer 216AR. Compared with the gate dielectric layer 224A-1, which is formed by oxidizing the epitaxial layer 200 formed of silicon carbide, for example, the gate dielectric layer 224A-2 is formed by oxidizing the conductive material 220AR (FIG. 9) formed of polysilicon, for example. Therefore, the gate dielectric layer 224A-2 may have a thicker thickness than the gate dielectric layer 224A-1. In addition, a top surface 224BT of the oxide layer 224B may be higher than the top surface 210T of the mask pattern 210P along the direction 310. After performing the oxidation process, the unoxidized conductive material 220AR in the trench 212A forms the first electrode 220F1, and the unoxidized conductive material 220B in the trench 212B is denoted as the conductive material 220BR.

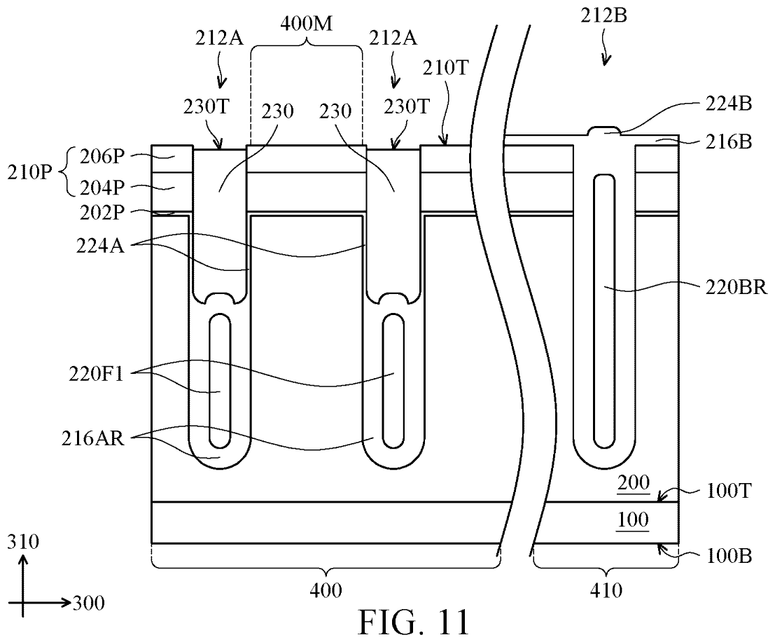

Next, as shown in FIG. 11, a deposition process and subsequent planarization process and etching process may be performed to form electrode material pillars 230 in the trenches 212A. Top surfaces 230T of the electrode material pillar 230 may be lower than the top surface 210T of the mask pattern 210P. In some embodiments, the electrode material pillars 230 and the conductive materials 220AR, 220BR may include the same material, such as polycrystalline silicon. In some embodiments, the deposition process may include metal organic chemical vapor deposition (MOCVD), sputtering, resistance heating evaporation, electron beam evaporation, or other suitable deposition processes. In some embodiments, the planarization process includes a chemical mechanical polishing (CMP) process. In some embodiments, the etching process includes a blanket etching process.

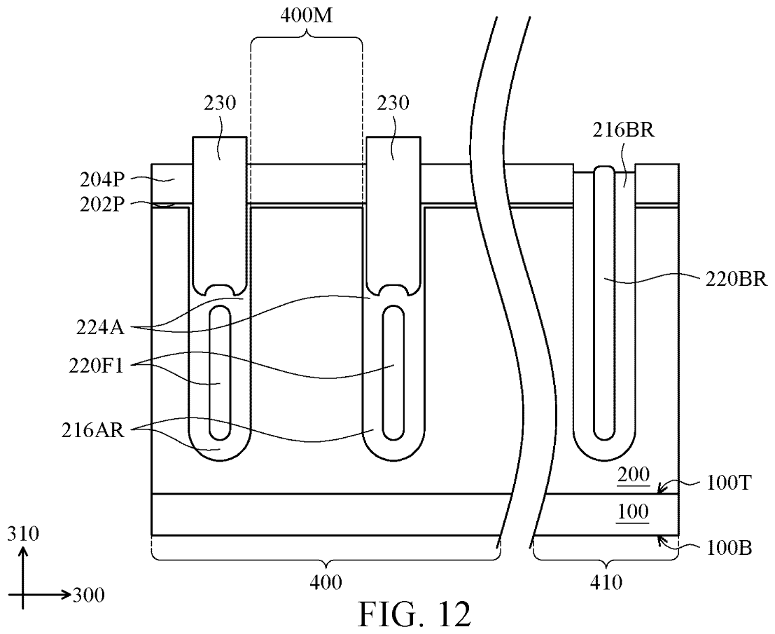

Next, as shown in FIG. 12, another etching process may be performed to remove the second mask pattern 206P of the mask pattern 210P to expose the first mask pattern 204P. In some embodiments, the first mask pattern 204P, the oxide layer 224B, and the mask dielectric layer 216B include the same insulating material, such as silicon oxide. Therefore, the etching process may also remove the oxide layer 224B and a portion of the shielding dielectric layer 216B. The remaining shielding dielectric layer 216B is denoted as the shielding dielectric layer 216BR. After performing the etching process, the electrode material pillar 230 may protrude from the first mask pattern 204P along the direction 310. In addition, the conductive material 220BR may protrude from the shielding dielectric layer 216BR along the direction 310. In some embodiments, the etching process includes wet etching.

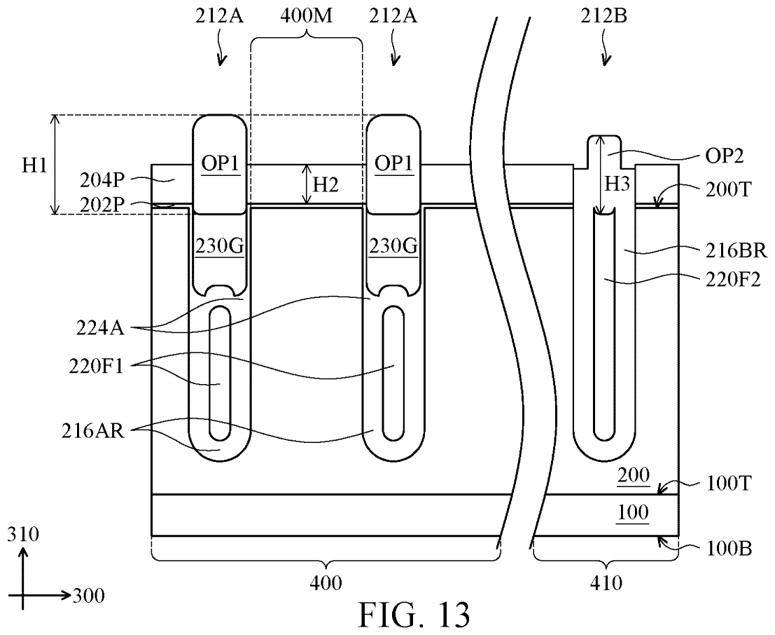

Next, as shown in FIG. 13, another oxidation process may be performed to oxidize the top of the electrode material pillar 230 (the portion close to the top surface 230T) as the insulating pillar OP1. In addition, the oxidation process may be performed to oxidize the top of the conductive material 220BR to form the insulating pillar OP2. After the oxidation process is performed, the unoxidized electrode material pillar 230 may form the gate electrode 230G in the trench 212A, and the unoxidized conductive material 220BR may form the second electrode 220F2 in the trench 212B. As shown in FIG. 13, the insulating pillars OP1 and OP2 may protrude from the top surface 200T of the epitaxial layer 200 and the first mask pattern 204P along the direction 310. In the direction 310, the insulating pillar OP1 has a thickness H1, and the first mask pattern 204P has a thickness H2. In some embodiments, the ratio of the thickness H1 to the thickness H2 is between about 3 and 5. If the ratio of the thickness H1 to the thickness H2 is less than 3, the thickness of the insulating pillar OP1 protruding from the second mask pattern 206P is too small to form the dielectric spacers on the opposite sidewalls of the insulating pillar OP1 in the subsequent processes. If the ratio of the thickness H1 to the thickness H2 is greater than 5, it may not be possible to form the dielectric spacers with sufficient lateral width (along direction 300) on the opposite sidewalls of the insulating pillar OP1. In addition, the insulating pillar OP2 may have a thickness H3 in the direction 310. In some embodiments, since the width of the electrode material column 230 is greater than the width of the second electrode 220F2 in the direction 300, the thickness H3 may be less than the thickness H1.

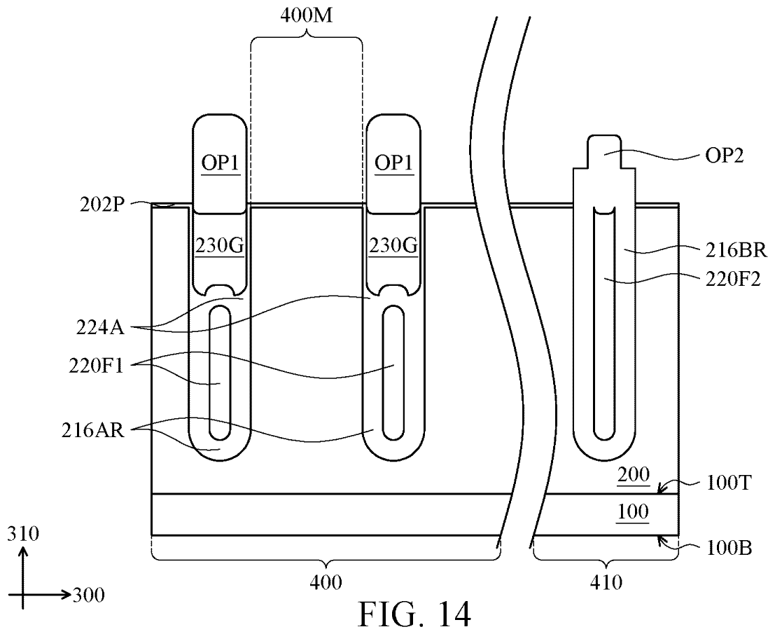

Next, as shown in FIG. 14, another selective etching process may be performed to remove the first mask pattern 204P to expose the pad oxide layer 202P. In some embodiments, the insulating pillars OP1 and OP2 and the second mask pattern 206P include different insulating materials. For example, the insulating pillar OP1 is formed of silicon oxide, and the first mask pattern 204P is formed of silicon nitride. Therefore, the above selective etching process will not remove the insulating pillars OP1 and OP2 and the pad oxide layer 202P during the removal of the first mask pattern 204P. In some embodiments, the selective etching process includes wet etching.

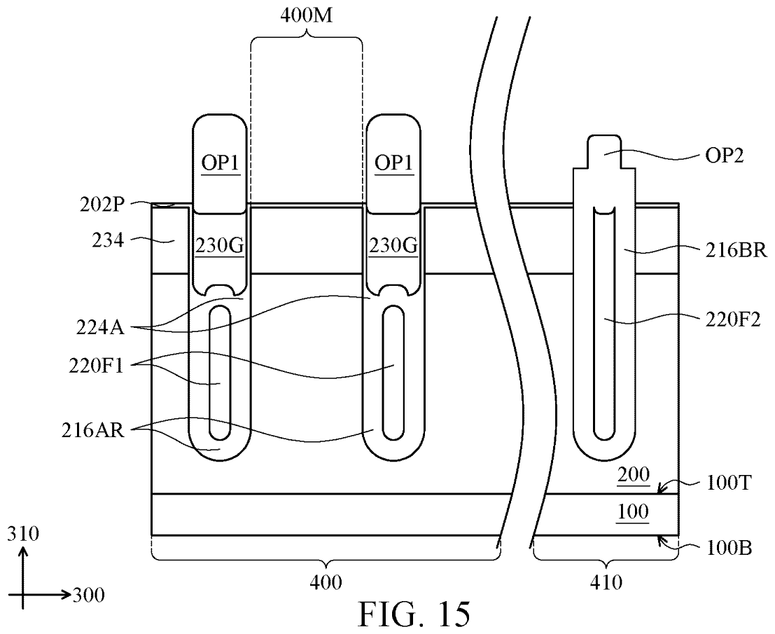

Next, as shown in FIG. 15, an ion implantation process may be performed to entirely form a well region 234 having the second conductivity type, such as a P-type well region 234, in the epitaxial layer 200. In some embodiments, the bottom surface 234B of the well region 234 is located above the first electrode 220F1 in the direction 310.

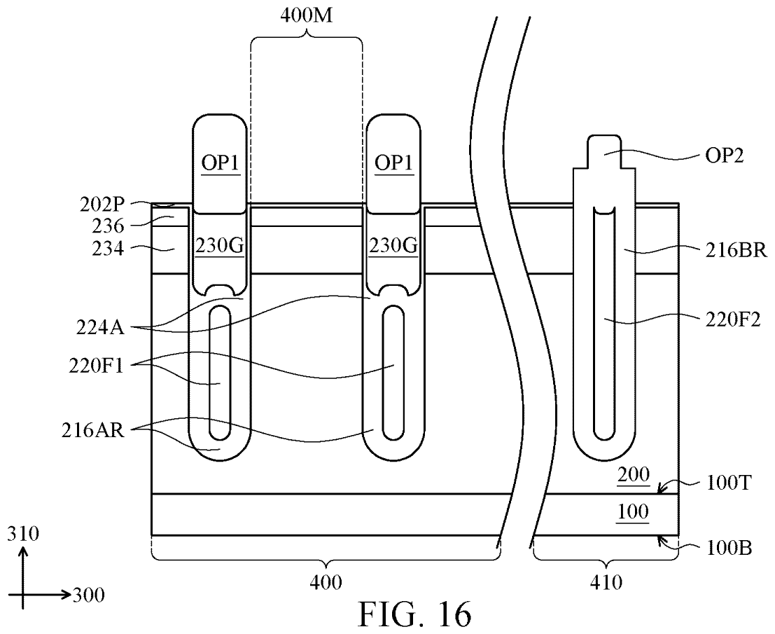

Next, as shown in FIG. 16, a photolithography process may be performed to form a photoresist pattern (not shown) over the epitaxial layer 200 in the second region 410 to expose the epitaxial layer 200 in the first region 400. Next, another ion implantation process is performed to form a source region 236 having the first conductivity type, such as an N-type source region 236, on the well region 234 of the first region 400. After forming the source region 236, the photoresist pattern is removed.

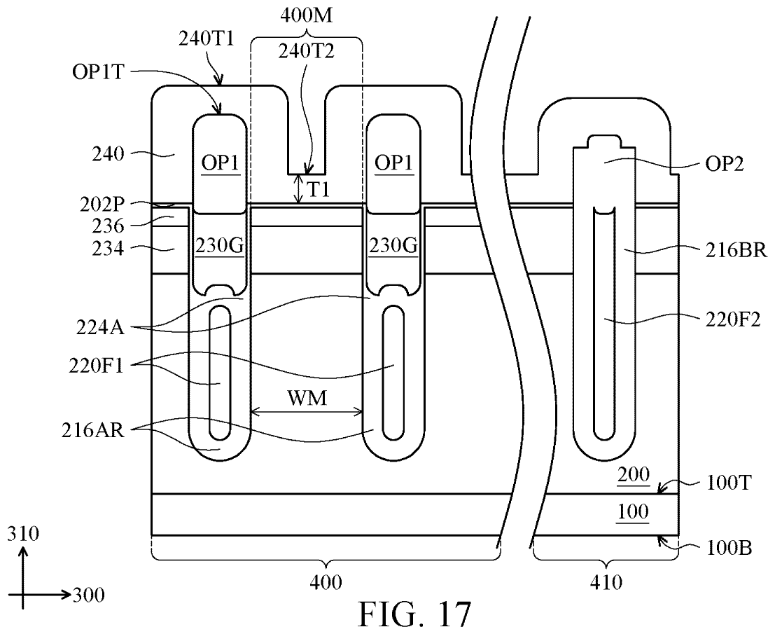

Next, as shown in FIG. 17, a deposition process may be performed to form an interlayer dielectric layer 240 on the epitaxial layer 200. The interlayer dielectric layer 240 has a thickness T1 along the direction 310. In some embodiments, the ratio of the mesa width WM to the thickness T1 may be controlled between about 2 and 3, so that the interlayer dielectric layer 240 is conformally formed on the insulating pillars OP1 and OP2 and the mesa region 400M. If the ratio of the mesa width WM to the thickness T1 is less than 2, it may not be possible to form the dielectric spacers with sufficient lateral width (along the direction 300) on the opposite sidewalls of the insulating pillar OP1. If the ratio of the mesa width WM to the thickness T1 is greater than 3, the interlayer dielectric layer 240 may fill up the space between the adjacent insulating pillars OP1 and cannot to form the dielectric spacers on the opposite sidewalls of the insulating pillars OP1 in subsequent processes. As shown in FIG. 17, an upper surface 240T1 of the interlayer dielectric layer 240 located above the top surface OP1T of the insulating pillar OP1 is higher than an upper surface 240T2 located above the epitaxial layer 200 in the mesa region 400M.

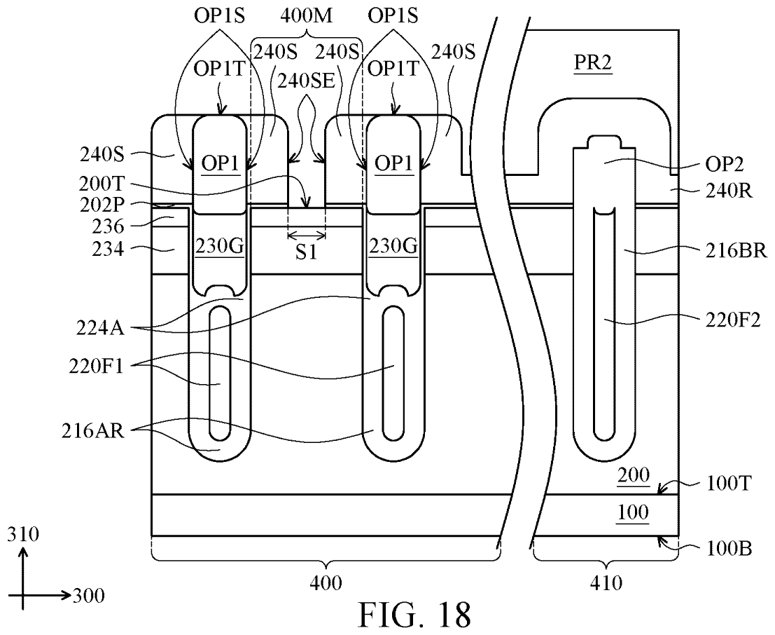

Next, as shown in FIG. 18, a photolithography process may be performed to form a photoresist pattern PR2 on the epitaxial layer 200 in the second region 410. The photoresist pattern PR2 may cover the interlayer dielectric layer 240 in the second region 410, so that the interlayer dielectric layer 240 in the first region 400 (FIG. 17) is exposed from the photoresist pattern PR2. Next, an etching process is performed to remove a portion of the interlayer dielectric layer 240 from the epitaxial layer 200 in the mesa region 400M and the top surface OP1T of the insulating pillar OP1 until the top surface 200T of the epitaxial layer 200 in the mesa region 400M is exposed, thereby forming the pair of dielectric spacers 240S on opposite sidewalls OP1S of each of the insulating pillars OP1. After the etching process is performed, the remaining interlayer dielectric layer 240 covered by the photoresist pattern PR2 is denoted as an interlayer dielectric layer 240R. Among the two pairs of dielectric spacers 240S formed on the opposite sidewalls OP1S of the two adjacent insulating pillars OP1, the two dielectric spacers 240S that are close to each other are located in the mesa region 400M. Furthermore, a distance S1 between the outer sidewalls 240SE of the two dielectric spacers 240S that are close to each other (along the direction 310) may define the lateral size of the subsequently formed contact hole. After the dielectric spacers 240S are formed, the photoresist pattern PR2 is removed.

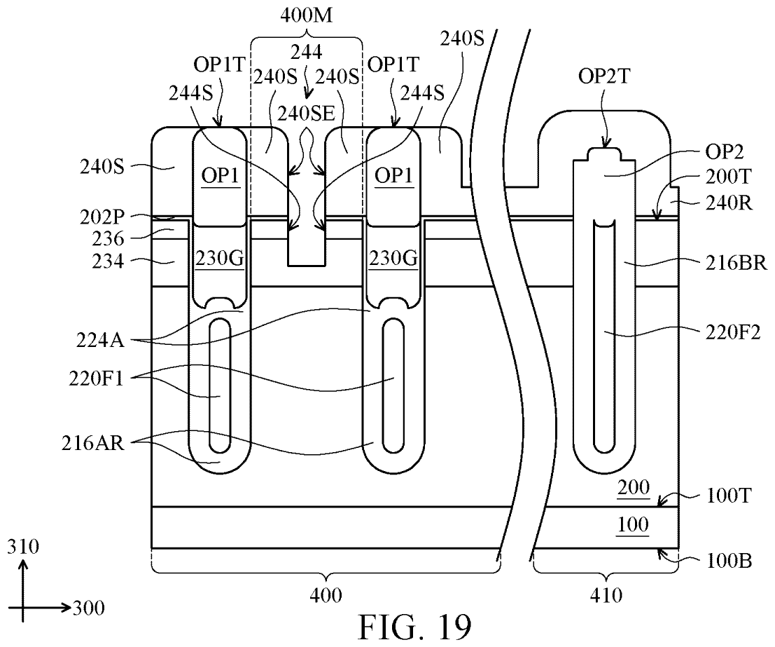

Next, as shown in FIG. 19, an etching process may be performed to form a contact hole 244 in the epitaxial layer 200 in the first region 400 using the insulating pillar OP1, the dielectric spacer 240S and the interlayer dielectric layer 240R collectively as an etching mask. The etching process may remove a portion of the epitaxial layer 200 exposed from the two adjacent dielectric spacers 240S of the two adjacent pairs of dielectric spacers 240S that are close to each other to form the contact hole 244. A bottom surface 244B of the contact hole 244 may be located above the bottom surface 234B of the well region 234. During the formation of the contact hole 244, the remaining interlayer dielectric layer 240R covers the top surface OP2T and the opposite sidewall of the insulating pillar OP2. In some embodiments, the etching process including a blanket etching process may etch a portion of the epitaxial layer 200 in the first region 400 along the outer sidewalls 240SE of the dielectric spacers 240S that are close to each other in an anisotropic manner without using any photoresist pattern. Therefore, sidewall 244S of the contact hole 244 is self-aligned with the outer sidewalls 240SE of the two dielectric spacers 240S that are close to each other.

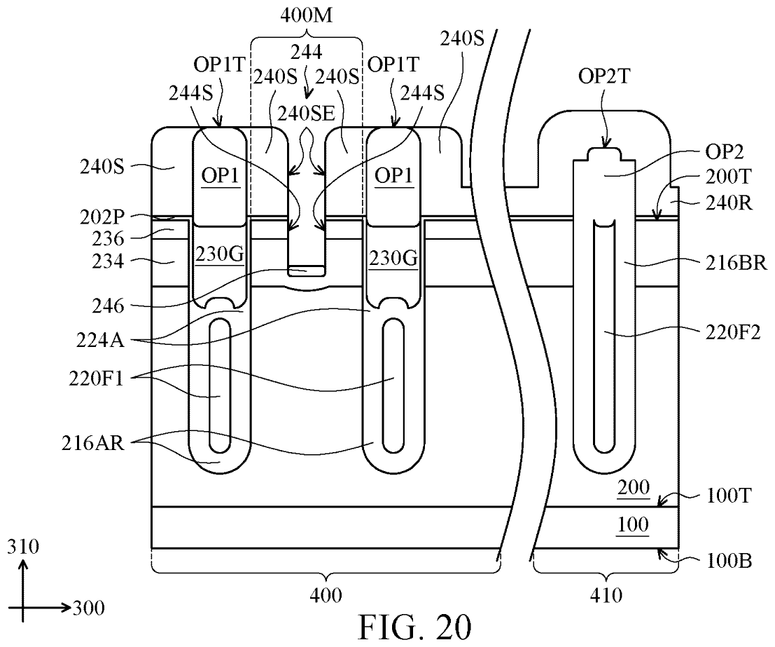

Next, as shown in FIG. 20, an ion implantation process may be performed to form a contact doped region 246 in the epitaxial layer 200 under the bottom surface 244B of the contact hole 244 using the insulating pillar OP1, the dielectric spacer 240S and the interlayer dielectric layer 240R collectively as a mask. The contact doped region 246, such as P-type contact doped region 246, and the well region 234 have the same conductivity type. Furthermore, the doping concentration of the contact doped region 246 is greater than the doping concentration of the well region 234. For example, when the well region 234 is a P-type well region 234, the contact doping region 246 is a P-type heavily doped (P+) contact doping region 246 to serve as a pick-up doping region of the well region 234. After performing the ion implantation process, an annealing process may be performed to activate the dopants in the well region 234, the source region 236 and the contact doping region 246. In some embodiments, the annealing process includes laser annealing, rapid thermal annealing (RTA), other suitable annealing processes, or a combination thereof.

Next, as shown in FIG. 1, a deposition process may be performed to form a contact barrier layer (not shown) on the dielectric spacer 240S and the interlayer dielectric layer 240R. The contact barrier layer is conformally deposited in the contact hole 244 (FIG. 19). Next, a contact conductive layer (not shown) is deposited above the barrier material layer. The contact conductive layer may fill up the remaining space in the contact hole 244. Next, a removal process (such as an etching process or a planarization process) is performed to remove excess portions of the contact barrier layer and the contact conductive layer over the dielectric spacers 240S and the interlayer dielectric layer 240R, so as to form the contact feature 250 in the contact hole 244. The removal process may also remove a portion of the insulating pillar OP1, the dielectric spacer 240S and the interlayer dielectric layer 240R, so that the contact feature 250, the insulating pillar OP1 and the dielectric spacer 240S in the first region 400 and the interlayer dielectric layer 240R in the second region 410 are coplanar each other. The contact feature 250 fills the contact hole 244 and is electrically connected to the source region 236 and the well region 234. After performing the removal process, the top surface of the remaining insulating pillar OP1 is denoted as the top surface OP1T′ of the remaining insulating pillar OP1.

Next, as shown in FIG. 1, after the contact feature 250 is formed, a deposition process may be performed to entirely form a metal layer 254 on the contact feature 250, the insulating pillar OP1 and the dielectric spacer 240S in the first region 400 and the dielectric layer 240R in the second region 410. In some embodiments, the deposition process may include a physical vapor deposition (PVD) process, a chemical vapor deposition (CVD) process, another suitable process, or a combination thereof.

Subsequent processes may be further performed to form a drain contact (not shown) on the bottom surface 100B of the silicon carbide substrate 100. The drain contact may be electrically connected to the silicon carbide substrate 100. After performing the aforementioned processes, the semiconductor device 500 is formed.

Embodiments provide a semiconductor device and a method for forming the same. The method for forming the semiconductor device includes using an oxidation process to oxidize the top surface of the electrode material pillar for forming the gate electrode to form an insulating pillar protruding from the top surface of the epitaxial layer. Next, a pair of dielectric spacers is formed on opposite sidewalls of the insulating pillar. The contact hole may be formed in the epitaxial layer using the dielectric spacers as an etching mask without using any photoresist pattern. Because the position of the contact hole is defined by the dielectric spacers of two adjacent pairs of dielectric spacers that are close to each other. Therefore, the contact feature may be accurately formed in the middle position of two adjacent trenches without using the photolithography process. The contact-to-trench overlay errors and subsequent photoresist rework problems caused by the conventional photolithography process can be avoided. The uniformity of electrical performances and the reliability of the semiconductor device are improved. When the density of the component is increased, the cost of the high-resolution photomasks and the photolithography process can be reduced.

In a direction substantially perpendicular to the top surface of the silicon carbide substrate (e.g., the direction 310), the silicon oxide insulating pillar may protrude from the silicon nitride mask pattern on the epitaxial layer. In some embodiments, the ratio of the thickness of the silicon oxide insulating pillar (e.g., the thickness H1) to the thickness of the silicon nitride mask pattern (e.g., the thickness H2) may be between about 3 and 5 to facilitate forming the dielectric spacers on the opposite sidewalls of the insulating pillar in the subsequent processes. The dielectric spacers may be formed by patterning an interlayer dielectric layer over the insulating pillar. In some embodiments, the ratio of the mesa width (e.g., the mesa width WM) to the thickness of the interlayer dielectric layer (e.g., the thickness T1) can be controlled between about 2 and 3, so that the interlayer dielectric layer may be conformally formed on the insulating pillar and the mesa region. The dielectric spacers having an appropriate lateral dimension may be formed by the subsequent etching processes. Next, the contact feature having an appropriate lateral dimension is accordingly formed.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a silicon carbide substrate, wherein the silicon carbide substrate has a first region and a second region, and has a first conductivity type;
an epitaxial layer disposed on a top surface of the silicon carbide substrate, wherein the epitaxial layer has the first conductivity type;
a well region located in the epitaxial layer, wherein the well region has a second conductivity type;
a gate structure disposed in the epitaxial layer in the first region, wherein the gate structure extends in a first direction;
a first insulating pillar disposed directly above the gate structure and protruding from a top surface of the epitaxial layer in the first direction;
a pair of first dielectric spacers disposed on opposite sidewalls of the first insulating pillar; and
a contact feature extending from above the epitaxial layer into the well region, wherein a first sidewall of the contact feature in the epitaxial layer is aligned with a first outer sidewall of one of the pair of first dielectric spacers.

2. The semiconductor device as claimed in claim 1, further comprising:
a first electrode disposed in the epitaxial layer in the first region, located directly below the gate structure and extending in the first direction, wherein the gate structure comprises a gate electrode and a gate dielectric layer, and the gate electrode is separated from the first electrode by the gate dielectric layer;
a second electrode disposed in the epitaxial layer in the second region and extending in the first direction;
a second insulating pillar disposed directly above the second electrode and protruding from the top surface of the epitaxial layer in the first direction; and
a source region located on the well region in the first region and close to the top surface of the epitaxial layer, wherein the source region has the first conductivity type.

3. The semiconductor device as claimed in claim 2, wherein the first insulating pillar completely covers and is in contact with a top surface of the gate electrode.

4. The semiconductor device as claimed in claim 2, wherein a top surface of the gate electrode is lower than the top surface of the epitaxial layer.

5. The semiconductor device as claimed in claim 2, wherein in a second direction, a first width of the gate electrode is the same as a second width of the first insulating pillar.

6. The semiconductor device as claimed in claim 5, wherein in a second direction, a third width of the second electrode is the same as a fourth width of the second insulating pillar.

7. The semiconductor device as claimed in claim 6, wherein the fourth width is smaller than the second width.

8. The semiconductor device as claimed in claim 7, wherein in the first direction, a first distance between the first insulating pillar and the top surface of the epitaxial layer is greater than a second distance between the second insulating pillar and the top surface of the epitaxial layer.

9. The semiconductor device as claimed in claim 1, further comprising:
a further gate structure disposed in the epitaxial layer in the first region, wherein the further gate structure is separated from the gate structure by the epitaxial layer along a second direction, wherein the first direction is perpendicular to the second direction,
wherein the contact feature is located between the gate structure and the further gate structure along the second direction.

10. The semiconductor device as claimed in claim 9, further comprising:
a further first insulating pillar disposed directly above the further gate structure and protruding from the top surface of the epitaxial layer in the first direction;
a further pair of first dielectric spacers disposed on opposite sidewalls of the further first insulating pillar,
wherein the contact feature is adjacent to one of the further pair of first dielectric spacers and extends into the well region of the first region, wherein a second sidewall of the contact feature in the epitaxial layer is aligned with a second outer sidewall of one of the further pair of first dielectric spacers.

11. A method for forming a semiconductor device, comprising:
providing a silicon carbide substrate, wherein the silicon carbide substrate has a first region and a second region, and the silicon carbide substrate has a first conductivity type;
growing an epitaxial layer on a top surface of the silicon carbide substrate, wherein the epitaxial layer has the first conductivity type;
forming a first trench in the epitaxial layer in the first region along a first direction;
forming an electrode material pillar in the first trench;
oxidizing a top of the electrode material pillar to form a first insulating pillar, wherein the unoxidized electrode material pillar forms a gate electrode in the first trench, and wherein the first insulating pillar protrudes from a top surface of the epitaxial layer in the first direction;
forming a pair of first dielectric spacers on opposite sidewalls of the first insulating pillar;
performing an etching process to form a contact hole in the epitaxial layer using the pair of first dielectric spacers as an etching mask; and
forming a contact feature in the contact hole.

12. The method for forming a semiconductor device as claimed in claim 11, further comprising:
forming a mask pattern on the top surface of the epitaxial layer, wherein the first insulating pillar is formed of a first insulating material, the mask pattern is formed of a second insulating material, and the first insulating material is different from the second insulating material;
removing the epitaxial layer not covered by the mask pattern to form the first trench;
removing the mask pattern after forming the first insulating pillar;
forming a well region in the epitaxial layer after removing the mask pattern, wherein the well region has a second conductivity type; and
forming a source region on the well region of the first region, wherein the source region has the first conductivity type.

13. The method for forming a semiconductor device as claimed in claim 12, wherein, the first insulating pillar has a first thickness in the first direction, the mask pattern has a second thickness before removing the mask pattern, and a ratio of the first thickness to the second thickness is between 3 and 5.

14. The method for forming a semiconductor device as claimed in claim 12, further comprising:
forming a first electrode in a lower portion of the first trench before forming the electrode material pillar.

15. The method for forming a semiconductor device as claimed in claim 14, further comprising:
forming a second trench in the first direction in the epitaxial layer in the second region;
forming a second conductive material in the second trench; and
oxidizing a top of the second conductive material to form a second insulating pillar, wherein the unoxidized second conductive material forms a second electrode in the second trench, and the second insulating pillar protrudes from the top surface of the epitaxial layer in the first direction.

16. The method for forming a semiconductor device as claimed in claim 15, further comprising:
forming a first conductive material in the first trench during the formation of the second conductive material, wherein the first conductive material and the second conductive material comprise the same material;
forming a first photoresist pattern over the epitaxial layer in the second region;
removing a portion of the first conductive material from an upper portion of the first trench;
removing the first photoresist pattern; and
performing an oxidation process to form a first gate dielectric layer in the first trench, wherein forming the first gate dielectric layer comprises oxidizing a top of the first conductive material, wherein the unoxidized first conductive material forms the first electrode, and the top of the second conductive material is oxidized to form a second oxide layer during the oxidation process.

17. The method for forming a semiconductor device as claimed in claim 15, further comprising:
forming a further first trench in the epitaxial layer in the first region, wherein the further first trench and the first trench are separated from each other along a second direction to define a mesa region of the epitaxial layer, and wherein the mesa region has a mesa width along the second direction;
forming a further gate structure located in the further first trench and a further first insulating pillar located directly above the further gate structure; and
forming a further pair of first dielectric spacers on opposite sidewalls of the further first insulating pillar, wherein one of the pair of first dielectric spacers and one of the further pair of first dielectric spacers are located within the mesa region,
wherein a portion of the epitaxial layer exposed from the one of the pair of first dielectric spacers and the one of the further pair of first dielectric spacers is removed by the etching process to form the contact hole.

18. The method for forming a semiconductor device as claimed in claim 17, further comprising:
forming an interlayer dielectric layer on the epitaxial layer after forming the first insulating pillar and the second insulating pillar;
forming a second photoresist pattern on the epitaxial layer in the second region;
removing a portion of the interlayer dielectric layer from the epitaxial layer in the mesa region and the top surfaces of the first insulating pillar and the further first insulating pillar to form the pair of first dielectric spacers and the further pair of first dielectric spacers; and
removing the second photoresist pattern.

19. The method for forming a semiconductor device as claimed in claim 18, wherein the dielectric layer has a first thickness in the first direction, and the ratio of the mesa width to the first thickness is between 2 and 3.

20. The method for forming a semiconductor device as claimed in claim 18, wherein a first upper surface of the interlayer dielectric layer over the first insulating pillar is higher than a second upper surface of the interlayer dielectric layer over the mesa region.
